(19) United States
(12) Patent Application Publication
(10) Pub. No.: US 2026/0238163 A1
(43) Pub. Date: Aug. 13, 2026

(54) ACTIVE LOAD MODULATION PULLING METHOD FOR DOHERTY POWER AMPLIFIER

(71) Applicant: Southeast University, Nanjing, Jiangsu (CN)

(72) Inventors: Peng CHEN, Nanjing, Jiangsu (CN); Chao YU, Nanjing, Jiangsu (CN); Wei HONG, Nanjing, Jiangsu (CN)

(21) Appl. No.: 18/994,899

(22) PCT Filed: Mar. 23, 2023
(86) PCT No.: PCT/CN2023/083526

§ 371 Date: Jan. 15, 2025

(30) Foreign Application Priority Data
Feb. 21, 2023 (CN) 202310163015.9

(51) Int. Cl. H03F 1/02; H03F 1/56; H03F 3/24

(52) U.S. Cl. CPC H03F 1/0288; H03F 1/56; H03F 3/245

(57) ABSTRACT

An active load modulation pulling method for a Doherty power amplifier mainly solves the problem that existing load pulling methods cannot simulate non-linear interactions between a carrier transistor and a peak transistor. The implementation steps thereof are: 1) a load pulling architecture comprising a carrier transistor and a peak transistor; 2) connecting an inverse model of an equivalent output parasitic circuit at an output end of each of the transistors to achieve a de-embedding effect; 3) connecting two sections of quarter-wavelength impedance converters after the inverse models to achieve impedance conversion; 4) setting a signal source having optimal fundamental wave source impedance and a phase difference of 90° for the carrier transistor and the peak transistor, respectively; and 5) simulating the non-linear interaction of the transistors by means of changing the fundamental wave load impedances and input powers of the transistors.

### CROSS REFERENCE TO RELATED APPLICATIONS

This application is a National Stage of International Application No. PCT/CN2023/083526, filed on Mar. 23, 2023, which claims priority of application No. 202310163015.9 filed in China on Feb. 21, 2023 under 35 U.S.C. § 119, the entire contents of both of which are hereby incorporated by reference.

### TECHNICAL FIELD

The present disclosure relates to the technical field of power amplifiers, and specifically to an active load modulation pulling method for a Doherty power amplifier.

### BACKGROUND

In the fifth generation and future mobile communication systems, a large-scale MIMO technology can not merely improve the system capacity and the spectrum efficiency, but also improve user experience by reducing the wireless network interference. The RF power amplifier is the core component that consumes the most energy in the MIMO technology architecture, which converts DC energy into RF energy to amplify the output power of the RF signal. Therefore, the communication system requires the RF power amplifier to maintain a high-efficiency operating state in a large power back-off range. Due to simplicity of implementation, the Doherty power amplifier is widely used in base station systems and is one of the solutions that effectively improves the overall efficiency and power capacity of the system.

Currently, there are relatively few active load modulation pulling methods for the Doherty power amplifier. Traditional methods for Doherty power amplifiers include theoretical analysis methods and load pulling methods.

Theoretical analytical methods generally merely consider the operating state of power saturation and back-off (for example, 6 dB back-off), and theoretically calculate the relations between the load impedance of the carrier transistor and the peak transistor on the reference plane of the current generator. The load pulling method performs independent load pulling on the carrier transistor and the peak transistor, respectively, and analyzes the optimal load impedance at power saturation and back-off based on simulated or measured efficiency, output power and other data. However, since these two methods cannot simulate the nonlinear interaction between the carrier transistor and the peak transistor, the optimal load modulation trajectory of the Doherty power amplifier can not be predicted accurately.

### SUMMARY

The technical problems: in order to solve the problem that the current active load modulation pulling method for a Doherty power amplifier cannot simulate the nonlinear interaction between the transistors, the present disclosure provides an active load modulation pulling method for a Doherty power amplifier, which can accurately predict the nonlinear interaction between the carrier transistor and the peak transistor as well as the optimal load modulation trajectories.

The technical solutions: in order to achieve the above objectives, an active load modulation pulling method for a Doherty power amplifier of the present disclosure adopts the technical solutions as follows.

Disclosed is the load modulation pulling method, based on a carrier transistor, a peak transistor, an equivalent output parasitic circuit inverse model, a quarter-wavelength impedance converter and an input signal source of an initialization phase. The carrier transistor and the peak transistor are respectively connected to the equivalent output parasitic circuit inverse model, configured to de-embed an output parasitic circuit of the transistor, and obtain a load impedance on a reference plane of a current generator. A quarter-wavelength impedance converter before a combining point is connected to an equivalent output parasitic circuit inverse model of the carrier transistor, configured to converse a fundamental wave load impedance on the reference plane of the current generator, to implement a load modulation on a fundamental wave load impedance of the carrier transistor under different input powers. A quarter-wavelength impedance converter after the combining point is configured to match a combined impedance to a terminal impedance. The input signal source of the initialization phase is set with an optimal fundamental wave source impedance of the carrier transistor and an optimal fundamental wave source impedance of the peak transistor respectively, and a phase difference between two input signals is 90°. For one certain operating frequency, the active load modulation pulling method varies an indirect load impedance of the carrier transistor and an indirect load impedance of the peak transistor after the equivalent output parasitic circuit inverse model, and simultaneously varies an input power of the carrier transistor and an input power of the peak transistor, to simulate a simulation of a nonlinear interaction between the carrier transistor and the peak transistor, and obtain a load modulation trajectory that varies with the output power.

A load modulation pulling architecture is in a symmetrical form or an asymmetrical form, including one carrier transistor and one or more peak transistors.

The equivalent output parasitic circuit inverse model is a circuit model or a behavioral model, configured to offset an output parasitic circuit of the carrier transistor and an output parasitic circuit of the peak transistor to obtain the load impedance on the reference plane of the current generator.

An impedance converter before the combining point is not limited to a quarter-wavelength transmission line, or other transmission lines equivalent to the quarter-wavelength, and a function of the impedance converter before the combining point is to implement the load modulation of the fundamental wave load impedance of the carrier transistor.

An impedance converter after the combining point is not limited to a quarter-wavelength transmission line, or other transmission lines equivalent to the quarter-wavelength, and a function of the impedance converter after the combining point is to match the combined impedance to the terminal impedance.

The input signal source of the initialization phase is not limited to using two input signal sources, or being implemented by using other power distribution components with a phase difference of 90°.

A power distribution component is a 90° directional coupler.

The indirect load impedance after the equivalent output parasitic circuit inverse model is an impedance indirectly seen by the carrier transistor and the peak transistor on the reference plane of the current generator, and the value for the indirect load impedance is scanned and an input power is changed at the same time, thereby implementing the nonlinear interaction between the simulated transistors and obtaining the load modulation trajectory that varies with the output power.

Disclosed by the present disclosure is the active load modulation pulling method for the Doherty power amplifier, and the method includes following steps.

In S1, the load pulling architecture includes the carrier transistor and the peak transistor.

In S2, the fundamental wave load impedance on the reference plane of the current generator is obtained by respectively connecting the equivalent output parasitic circuit inverse model at an output of the carrier transistor and the peak transistor through a de-embedding means.

In S3, the quarter-wavelength converter is connected before the combining point on the reference plane of the current generator of the carrier transistor, to implement the load modulation on the fundamental wave load impedance of the carrier transistor under different input powers.

In S4, the quarter-wavelength impedance converter is connected after the combining point of the carrier transistor and the peak transistor, to match the combined impedance to the terminal impedance.

In S5, the optimal fundamental wave source impedance for the carrier transistor and the optimal fundamental wave source impedance for the peak transistor are set respectively at an input terminal port, an input signal phase of the carrier transistor is 0°, while an input signal phase of the peak transistor is −90°.

In S6, for one certain operating frequency, the nonlinear interaction between the transistors is simulated by varying the indirect load impedance of the carrier transistor and the indirect load impedance of the peak transistor and varying the input power of the carrier transistor and the input power of the peak transistor simultaneously, and the load modulation trajectory that varies with the output power is obtained.

Beneficial effects: In comparison with the prior art, the present disclosure can simulate the nonlinear interaction between the transistors in a Doherty power amplifier, thereby accurately predicting the optimal load modulation trajectories of the transistors, which is helpful for the design of the Doherty power amplifier. In addition, the present disclosure can be applied to the design of power amplifiers with multi-transistor load modulation by expansions.

### BRIEF DESCRIPTION OF THE DRAWINGS

FIG. 1 illustrates a schematic diagram of an active load modulation pulling method for a Doherty power amplifier in a specific embodiment of the present disclosure.

FIG. 2 illustrates a flow chart of an active load modulation pulling method in a specific embodiment of the present disclosure.

FIG. 3 illustrates an equivalent output parasitic circuit of a gallium nitride transistor in a specific embodiment of the present disclosure.

FIG. 4 illustrates a curve of an operating performance that varies with a power obtained by load pulling at 26 GHz in a specific embodiment of the present disclosure; (a) illustrates a curve of the power added efficiency that varies with an output power; and (b) illustrates a curve of a gain that varies with the output power.

FIG. 5 illustrates a diagram showing an optimal load modulation trajectory obtained by load pulling and a load modulation trajectory implemented by design in a specific embodiment of the present disclosure.

FIG. 6 illustrates an electromagnetic simulation result and an experimental measurement result of a designed and implemented Doherty power amplifier in a specific embodiment of the present disclosure, (a) illustrates an operating performance at 25.5 GHZ, (b) illustrates an operating performance at 26 GHZ, (c) illustrates an operating performance at 26.5 GHz, and (d) illustrates an operating performance at 27 GHz of the present disclosure.

### DETAILED DESCRIPTION OF THE EMBODIMENTS

The technical solutions of the present disclosure are further introduced below in conjunction with the specific embodiments and accompanying drawings.

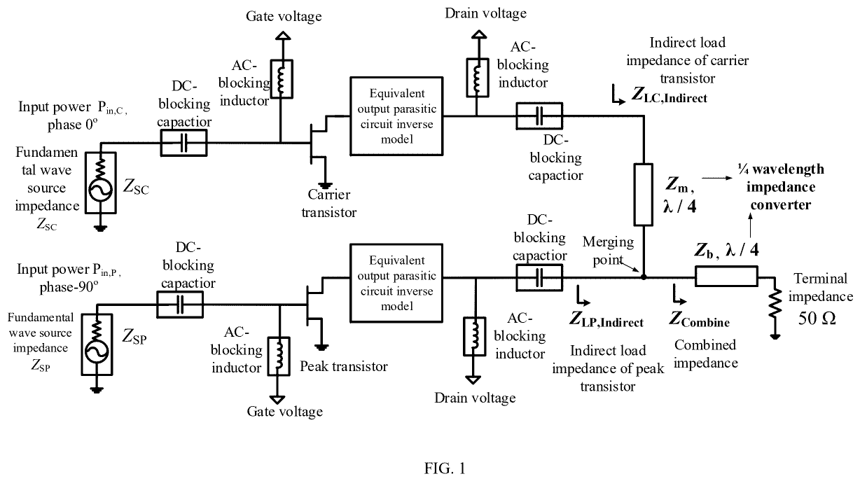

As illustrated in FIG. 1, the load modulation pulling method is based on a carrier transistor, a peak transistor, an equivalent output parasitic circuit inverse model, a quarter-wavelength impedance converter and an input signal source of an initialization phase. The carrier transistor and the peak transistor are respectively connected to the equivalent output parasitic circuit inverse model, configured to de-embed output parasitic circuits of the carrier transistor and the peak transistor, and obtain a load impedance on a reference plane of a current generator. A quarter-wavelength impedance converter before a combining point is connected to an equivalent output parasitic circuit inverse model of the carrier transistor, configured to converse the fundamental wave load impedance on the reference plane of the current generator, to implement a load modulation on the fundamental wave load impedance of the carrier transistor under different input powers. A quarter-wavelength impedance converter after the combining point is configured to match a combined impedance to a terminal impedance. The input signal source of the initialization phase is set with an optimal fundamental wave source impedance of the carrier transistor and an optimal fundamental wave source impedance of the peak transistor respectively, and a phase difference between two input signals is 90°. For one certain operating frequency, the active load modulation pulling method varies an indirect load impedance of the carrier transistor and an indirect load impedance of the peak transistor after the equivalent output parasitic circuit inverse model, and simultaneously varies an input power of the carrier transistor and an input power of the peak transistor, to simulate a simulation of a nonlinear interaction between the carrier transistor and the peak transistor, and obtain a load modulation trajectory that varies with the output power.

Further, according to the operating principle of the Doherty power amplifier, the characteristic impedance Zₘ of the quarter-wavelength impedance converter before the combining point can be calculated by Formula (1):

$${Z}_{m} = γ \frac{{Z}_{Combme} \times ( {Z}_{LP , Indirect} ) *}{{Z}_{Combme} + ( {Z}_{LP , Indirect} ) *} \qquad ( 1 )$$

where in Formula (1), Z_{Combine} denotes a combined impedance, Z_{LP,Indirect} and (Z_{LP,Indirect})* denote the peak transistor indirect load impedance and the conjugate value for the peak transistor indirect load impedance, respectively, and γ denotes the ratio of the maximum drain current of the carrier transistor to the drain current at the back-off point, which is used to denote the back-off interval of the Doherty power amplifier. For example, in a case where γ=2, 20 log₁₀(γ)=6 dB, which denotes that the Doherty power amplifier has a back-off interval of 6 dB.

Further, according to the quarter-impedance conversion relation, the indirect load impedance Z_{LC,Indirec} of the carrier transistor can be calculated by Formula (2):

$${Z}_{LC , Indirect} = {Z}_{m}^{2} \frac{{Z}_{Combme} + ( {Z}_{LP , Indirect} ) *}{{Z}_{Combme} \times ( {Z}_{LP , Indirect} ) *} \qquad ( 2 )$$

Formula (1) is substituted into Formula (2), and Formula (3) is derived:

$${Z}_{LC , Indirect} = {γ}^{2} \frac{{Z}_{Combme} \times ( {Z}_{LP , Indirect} ) *}{{Z}_{Combme} + ( {Z}_{LP , Indirect} ) *} \qquad ( 3 )$$

Further, by processing Formula (3), the combined impedance can be calculated by Formula (4):

$${Z}_{Combme} = \frac{{Z}_{LC , Indirect} \times ( {Z}_{LP , Indirect} ) *}{{γ}^{2} ( {Z}_{LP , Indirect} ) * - {Z}_{LC , Indirect}} \qquad ( 4 )$$

Further, the characteristic impedance Z_{b} of the quarter-wavelength impedance converter after the combining point can be calculated by Formula (5):

$${Z}_{b} = \sqrt{{Z}_{Combme} \times {R}_{L}} \qquad ( 5 )$$

where in Formula (5), R_{L} denotes the terminal impedance, is generally 50Ω.

Further, according to Formulas (1), (4) and (5), the characteristic impedances Zₘ and Z_{b} of the two sections of the quarter-wavelength impedance converters before and after the combining point can be calculated from the three known variables γ, Z_{LC,Indirect} and Z_{LP,Indirect}.

In a case where the two sections of the quarter-wavelength impedance converters are determined, a simulation of the nonlinear interaction between the transistors in the Doherty power amplifier is implemented.

In a specific embodiment of the present disclosure, the Doherty power amplifier is composed of two 4×75 μm gallium nitride (GaN) high electron mobility transistors (HEMT) that respectively constitute a carrier transistor and a peak transistor, with an operating frequency band of 25.5 GHz to 27 GHz and a gallium nitride-silicon carbide process with a gate length of 150 nm is utilized.

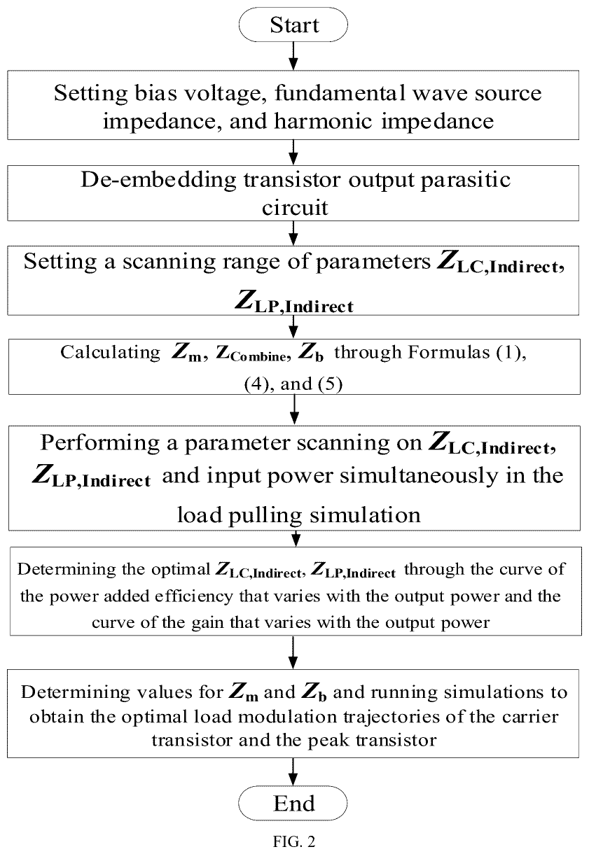

As illustrated in FIG. 2, the specific implementations of the active load modulation pulling method for the Doherty power amplifier are as follows.

In S1, the gate voltage of the carrier transistor is set to −1.78 V and the drain voltage of the carrier transistor is set to 23 V, and the gate voltage of the peak transistor is set to −3.5 V and the drain voltage of the peak transistor is set to 28 V. Subsequently, the optimal fundamental wave source impedance for the carrier transistor and the peak transistor are found respectively by the a source pulling means. The fundamental wave source impedances of the carrier transistor and the peak transistor are both set to (1.8+j5.7)Ω. The characteristic frequency of the used process is 34.5 GHZ, which can not effectively control the harmonics, thus the second and third harmonic impedances are set to 50Ω.

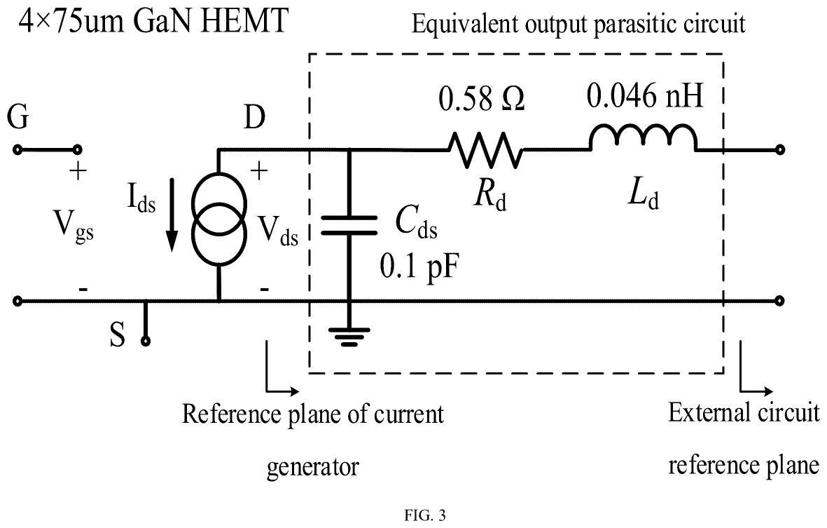

In S2, the equivalent output parasitic circuit of 4×75 μm GaN HEMT is illustrated in FIG. 3. The inverse model is simulated by de-embedding the output parasitic circuit of the transistors to obtain the load impedance of the transistors on the reference plane of the current generator.

In S3, the optimal load impedance of 4×75 μm GaN HEMT is calculated to be Rₒₚₜ=190Ω through the current-voltage characteristic curve by DC simulation. Therefore, based on this reference value, the parameter scanning range of the indirect load impedance Z_{LC,Indirect} is set to [150, 400]Ω, and the parameter scanning range of Z_{LP,Indirect} is set to [150, 600]Ω.

In S4, γ=2 is selected, that is, the Doherty power amplifier has a back-off interval of 6 dB. The characteristic impedance Zₘ of the quarter-wavelength impedance converter before the combining point, the combined impedance Z_{Combine}, and the characteristic impedance Z_{b} of the quarter-wavelength impedance converter after the combining point are calculated by Formulas (1), (4), and (5), respectively.

In S5, at 26 GHZ, the nonlinear interaction between the transistors is simulated by performing the parameter-scanning on the indirect load impedance of the carrier transistor and the peak transistor, and simultaneously varying the input power of the carrier transistor and the input power of the peak transistor.

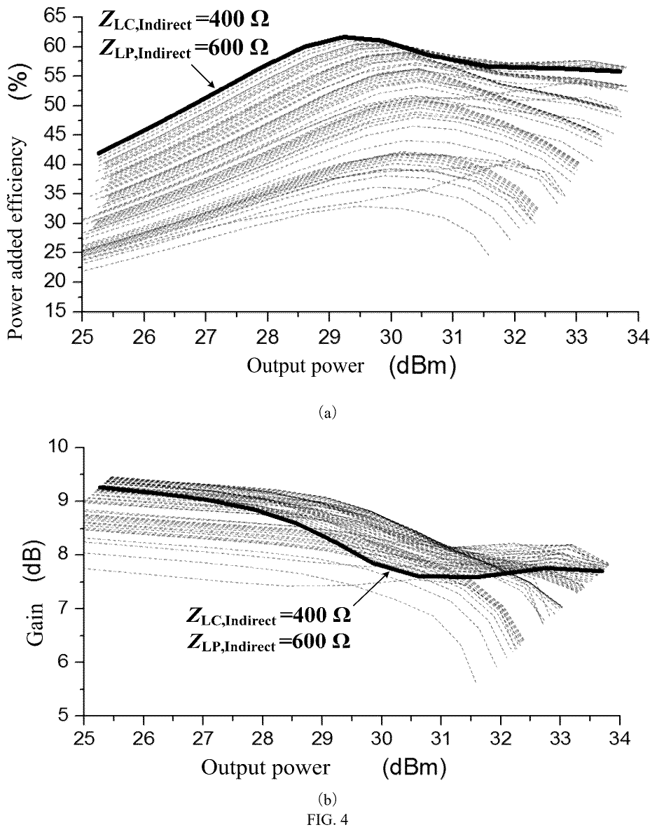

In S5, as illustrated in FIG. 4, based on the curve of the power added efficiency that varies with the output power and the curve of the gain that varies with the output power obtained by the active load modulation pulling method, the optimal Z_{LC,Indirect}=400Ω, and Z_{LP,Indirect}=600Ω are determined.

In S6, Z_{LC,Indirect}=400Ω, and Z_{LP,Indirect}=600Ω are substituted into Formulas (1), (4), and (5), Zₘ, Z_{b} are calculated again and the simulation is executed to obtain the optimal load modulation trajectories of the carrier transistor and the peak transistor at 26 GHz.

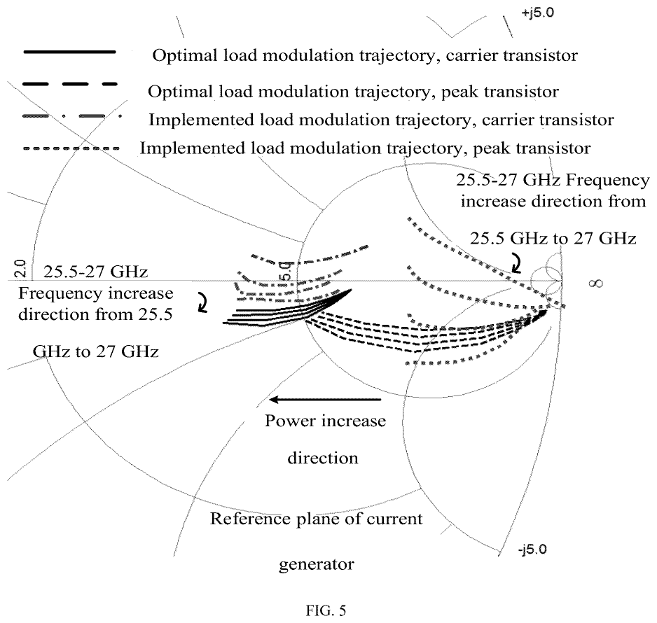

As illustrated in FIG. 5, through the specific embodiment, the optimal load modulation trajectories of the carrier transistor and the peak transistor at 25.5 GHZ, 26.5 GHz and 27 GHz are obtained respectively. By taking the optimal load modulation trajectory as the design goal, a Doherty power amplifier of 25.5 GHz to 27 GHz is designed and implemented. The optimal load modulation trajectory obtained by load pulling is compared with the load modulation trajectory implemented by the design in FIG. 5.

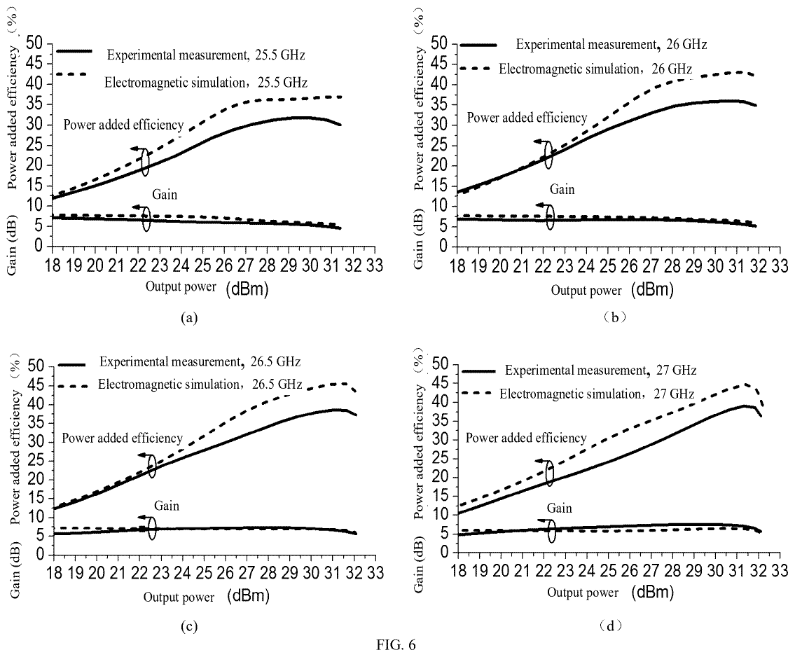

FIG. 6 illustrates the curves of the power added efficiency and gain that vary with output power of the designed and implemented Doherty power amplifier. The electromagnetic simulation results are basically similar to the experimental measurement results. The experimental measurement results show that within the operating frequency band of 25.5 GHZ to 27 GHz, the power added efficiency of the designed and implemented Doherty power amplifier is in a range from 30% to 37.2% at the power saturation and a range from 27% to 30.5% at 6 dB back-off, achieving the expected goal of high efficiency.

What is claimed is:

1. An active load modulation pulling method for a Doherty power amplifier, wherein the load modulation pulling method is based on a carrier transistor, a peak transistor, an equivalent output parasitic circuit inverse model, a quarter-wavelength impedance converter and an input signal source of an initialization phase;
the carrier transistor and the peak transistor are respectively connected to the equivalent output parasitic circuit inverse model, configured to de-embed output parasitic circuits of the carrier transistor and the peak transistor, and obtain a load impedance on a reference plane of a current generator;
a quarter-wavelength impedance converter before a combining point is connected to an equivalent output parasitic circuit inverse model of the carrier transistor, configured to converse a fundamental wave load impedance on the reference plane of the current generator, to implement a load modulation on a fundamental wave load impedance of the carrier transistor under different input powers;
a quarter-wavelength impedance converter after the combining point is configured to match a combined impedance to a terminal impedance;
the input signal source of the initialization phase is set with an optimal fundamental wave source impedance of the carrier transistor and an optimal fundamental wave source impedance of the peak transistor respectively, and a phase difference between two input signals is 90°; and
for one certain operating frequency, the active load modulation pulling method varies an indirect load impedance of the carrier transistor and an indirect load impedance of the peak transistor after the equivalent output parasitic circuit inverse model, and simultaneously varies an input power of the carrier transistor and an input power of the peak transistor, to simulate a nonlinear interaction between the carrier transistor and the peak transistor, and obtain a load modulation trajectory that varies with the output power.

2. The active load modulation pulling method for the Doherty power amplifier according to claim 1, wherein a load modulation pulling architecture is in a symmetrical form or an asymmetrical form, including one carrier transistor and one or more peak transistors.

3. The active load modulation pulling method for the Doherty power amplifier according to claim 1, wherein the equivalent output parasitic circuit inverse model is a circuit model or a behavioral model, configured to offset an output parasitic circuit of the carrier transistor and an output parasitic circuit of the peak transistor to obtain the load impedance on the reference plane of the current generator.

4. The active load modulation pulling method for the Doherty power amplifier according to claim 1, wherein an impedance converter before the combining point is not limited to a quarter-wavelength transmission line, or other transmission lines equivalent to the quarter-wavelength, and a function of the impedance converter before the combining point is to implement the load modulation of the fundamental wave load impedance of the carrier transistor.

5. The active load modulation pulling method for the Doherty power amplifier according to claim 1, wherein an impedance converter after the combining point is not limited to a quarter-wavelength transmission line, or other transmission lines equivalent to the quarter-wavelength, and a function of the impedance converter after the combining point is to match the combined impedance to the terminal impedance.

6. The active load modulation pulling method for the Doherty power amplifier according to claim 1, wherein the input signal source of the initialization phase is not limited to using two input signal sources, or being implemented by using other power distribution components with a phase difference of 90°.

7. The active load modulation pulling method for the Doherty power amplifier according to claim 1, wherein a power distribution component is a 90° directional coupler.

8. The active load modulation pulling method for the Doherty power amplifier according to claim 1, wherein the indirect load impedance after the equivalent output parasitic circuit inverse model is an impedance indirectly seen by the carrier transistor and the peak transistor on the reference plane of the current generator, and the value for the indirect load impedance is scanned and an input power is changed at the same time, thereby implementing the nonlinear interaction between the simulated transistors and obtaining the load modulation trajectory that varies with the output power.

9. The active load modulation pulling method for the Doherty power amplifier according to claim 1, wherein the method includes following steps:
S1, the load pulling architecture including the carrier transistor and the peak transistor;
S2, obtaining, by respectively connecting the equivalent output parasitic circuit inverse model at an output of the carrier transistor and the peak transistor, the fundamental wave load impedance on the reference plane of the current generator by a de-embedding means;
S3, connecting, before the combining point on the reference plane of the current generator of the carrier transistor, the quarter-wavelength converter, to implement the load modulation on the fundamental wave load impedance of the carrier transistor under different input powers;
S4, connecting, after the combining point of the carrier transistor and the peak transistor, the quarter-wavelength impedance converter, to match the combined impedance to the terminal impedance;
S5, respectively setting, at an input terminal port, the optimal fundamental wave source impedance for the carrier transistor and for the peak transistor, wherein an input signal phase of the carrier transistor is 0°, while an input signal phase of the peak transistor is −90°; and
S6, simulating, by varying the indirect load impedance of the carrier transistor and the indirect load impedance of the peak transistor and varying the input power of the carrier transistor and the input power of the peak transistor simultaneously, the nonlinear interaction between the transistors, for one certain operating frequency, and obtaining the load modulation trajectory that varies with the output power.
